(19) United States
(12) Patent Application Publication
(10) Pub. No.: US 2010/0066883 A1
(43) Pub. Date: Mar. 18, 2010

(54) SOLID-STATE IMAGING DEVICE AND METHOD FOR MANUFACTURING THE SAME

(75) Inventor: Makoto SIZUKUISI, Kanagawa (JP)

Correspondence Address: Studebaker & Brackett PC, One Fountain Square, 11911 Freedom Drive, Suite 750, Reston, VA, 20190, US

(73) Assignee: FUJIFILM CORPORATION, Tokyo (JP)

(21) Appl. No.: 12/560,016

(22) Filed: Sep. 15, 2009

(30) Foreign Application Priority Data
Sep. 16, 2008 (JP) P2008-236642

(51) Int. Cl. H04N 5/335; H01L 31/18

(52) U.S. Cl. 348/308; 438/73; 257/E21.211; 257/292; 348/E05.091

(57) ABSTRACT

A solid-state imaging device includes plural photosensitive elements 32, signal reading circuits and first type wiring 41 and 42. The photosensitive elements 32 are formed and arranged in a two-dimensional array state ion a light-receiving portion area of a semiconductor substrate 50. The signal reading circuits are formed so as to correspond to the respective photosensitive elements 32. Each signal reading circuit detects a captured image signal corresponding to signal charges of the photosensitive elements 32. The signal charges are accumulated in response to an amount of received light which comes from an object. The first type wiring 41 and 42 are formed of a high-concentration impurity diffused layer, are formed in one direction along a surface of the light-receiving portion area, and are connected to plural ones of the signal reading circuits which are provided along the one direction.

### CROSS-REFERENCE TO RELATED APPLICATIONS

This application claims the benefit of Japanese Patent Application No. 2008-236642 filed Sep. 16, 2008, the entire contents of which are hereby incorporated by reference, the same as if set forth at length.

### BACKGROUND OF THE INVENTION

1. Technical Field

The present invention relates to a solid-state imaging device formed on a semiconductor substrate and a method for manufacturing the same.

2. Related Art

FIG. 22A is a schematic surface view of a CMOS type solid-state imaging device of a related art in which a plurality of photodiodes (photoelectric conversion elements: photosensitive elements) are arranged in a grid form on a light-receiving surface (image area) of the surface of a semiconductor substrate, and FIG. 22B is a circuit diagram of the CMOS type solid-state imaging device. The CMOS type solid-state imaging device 1 shown in the figures has a large number of unit pixels 3 which are formed and arranged on the image area 2. A control pulse generation circuit (CPGC) 4 and a vertical scanning circuit (VSC) 5 are formed aside of the image area 2, and a noise suppression circuit 6 and a horizontal scanning circuit 7 are formed on a lower side of the image area 2.

The unit pixel 3 includes an n region 3a (see FIG. 23B) which forms a photodiode, and a signal reading circuit (although FIG. 22B shows a signal reading circuit composed of four transistors, it may be composed of three transistors) for reading signals detected by the n region 3a.

Wirings 10 extending in an X direction (a horizontal direction) and wirings 11 extending in a Y direction (a vertical direction) are laid on the image area 2 of the CMOS type solid-state imaging device 1. The wirings 10 are connected to the control pulse generation circuit 4 and the vertical scanning circuit 5, and the wirings 11 are connected to the noise suppression circuit 6 and the horizontal scanning circuit 7 or a power source.

The wirings 10, 11 which are laid in the X direction and the Y direction on the image area 2 will be referred to as “global wirings” to distinguish the wirings 10, 11 from, for example, an internal wiring of the signal reading circuit and internal wirings of the control pulse generation circuit 4, the vertical scanning circuit 5, the noise suppression circuit 6, and the horizontal scanning circuit 7. Examples of the global wirings include a row selection line, a row reset line, a power source line, an output signal line, etc., which are generally formed of metallic films such as aluminum or copper.

FIG. 23A is a schematic perspective view showing one unit pixel of the CMOS type solid-state imaging device, and FIG. 23B is a schematic section view thereof. A visible light beam 15 is incident through a microlens (top lens) 16 corresponding to each pixel and a color filter layer (e.g., red (R), green (G) or blue (B)) 17, etc., from outside into each of the unit pixels. The light beam reaches the n region 3a of the photodiode.

The n region 3a formed in the semiconductor substrate is separated, by an element isolation region 21, from a MOS transistor 22 constituting the signal reading circuit for signal selection and signal amplification. A gate electrode that of the MOS transistor 22 is formed between the element isolation regions 21 in the CMOS process, and a flattening protection film 23 is formed thereon. Then, a first wiring layer made of a metallic film such as aluminum is formed.

It is assumed that this first wiring layer is the global wiring 10 extending in the X direction, a further flattened insulation film is formed on the global wiring 10 extending in the X direction so that the global wiring 11 extending in the Y direction does not cross the global wiring 10 and is not electrically short-circuited. Then, the global wiring 11 extending in the Y direction is formed thereon.

Usually, a flattening film is still further formed thereon, and a light shielding film 19 is stacked. Then, another flattening film further stacked thereon, and a color filter layer 17 is stacked. The global wirings are generally formed in a multi-layered structure in the CMOS process. Therefore, a distance between the microlens 16 and the n region 3a, which constitutes the photodiode, become large.

The global wirings 10 and 11 manufactured by the multi-layered wiring technology obstructs a part of the incident light. The part of the incident light may be multiply-reflected between the global wirings 10 and 11 and/or between the global wirings 10, 11 and a metallic thin film (light shielding film: usually, an aluminum film) 19 for shielding from light the signal reading circuit 18 (Refer to FIG. 23A) other than the n region 3a. If multiply-reflected light 20 leaks into the n region 3a, a quality of a captured image would deteriorate.

Also, since the microlens 16 is away from the n region 3a constituting the photodiode, it becomes difficult to accurately condense the incident light onto the photodiode, which may cause color mixing and shading.

Then, JP 2007-81139 A (corresponding to US 2007/0064133 A1) describes that wirings 24 made of a polysilicon film is formed on the element isolation regions 21 as shown in FIG. 24, instead of wirings (for example, the global wiring 10 in FIG. 23B) equivalent to one layer of the global wirings. Also, the distance between the microlens 16 and the n region 3a is shortened. With this configuration, the light condensing efficiency of incident light into a photodiode is increased. However, the distance between the microlens 16 and the n region 3a is shortened only by one layer. Therefore, it is highly desired that the distance between the microlens and the photodiode is further shortened (the profile thereof is made further lower).

The example described above relates to the CMOS type solid-state imaging device of the related art. Also, CMOS type solid-state imaging devices of other types inherently have problems such as lowering in light condensing efficiency, color mixing and shading, which are caused by multiple reflections due to multi-layered wirings and a long distance between the microlenses and the photodiodes.

For example, a the solid-state imaging device described JP 2002-280537 A (corresponding to U.S. Pat. No. 6,781,178) is configured so that captured image signals are read by a signal reading circuit using a floating gate from each of plural photodiodes being formed in a grid form on an image area of a semiconductor substrate. However, it is necessary to lay global wirings over the image area as in the CMOS type solid-state imaging device described above. Therefore, multiple reflections, lowering in light condensing efficiency, color mixing, shading, lowering the profile, etc. might occur as in the above example.

### SUMMARY OF THE INVENTION

A solid-state imaging device provided with a signal reading circuit formed of a MOS transistor is configured so that global wiring layers of a multi-layered structure are formed on a semiconductor substrate on which photodiodes and signal reading circuits are formed, and that optical layers such as a color filter and microlens are stacked thereon. Therefore, a distance traveled by incident light until it reaches the photodiodes after passing through the microlens and the color filter layer becomes long. Multiple reflections, lowering in light condensing efficiency, color mixing, shading, and lowering the profile would occur.

The present invention provides a solid-state imaging device capable of increasing the incidence efficiency and avoiding color mixing and shading, by reducing multiple reflections of incident light due to global wirings and attempting to make a profile of the solid-state imaging device be lower. The invention also provides a method for manufacturing the solid-state imaging device.

According to an aspect of the invention, a solid-state imaging device includes a plurality of photosensitive elements, signal reading circuit and a first type wiring. The plurality of photosensitive elements are arranged in a two-dimensional array state in a light-receiving portion area of a semiconductor substrate. The signal reading circuits are formed so as to correspond to the respective photosensitive elements. Each signal reading circuit detects a captured image signal corresponding to signal charges of the corresponding one of the photosensitive elements. The signal charges are accumulated in response to an amount of light which come from an object and is received by the corresponding one of the photosensitive elements. The first type wiring is formed of a high-concentration impurity diffused layer. The first type wiring is formed in one direction along a surface of the light-receiving portion area and is connected to plural ones of the signal reading circuits which are arranged along the one direction.

According to another aspect of the invention, a method for manufacturing a solid-state imaging device includes: forming and arranging a plurality of photosensitive elements in a two-dimensional array state in a light-receiving portion area of a semiconductor substrate; forming signal reading circuits so as to correspond to the respective photosensitive elements, each signal reading circuit being formed to detect a captured image signal corresponding to signal charges of the corresponding one of the photosensitive elements, the signal charges being accumulated in response to an amount of light which come from an object and is received by the corresponding one of the photosensitive elements; and forming a first type wiring which is formed of a high-concentration impurity diffused layer, extend in one direction along a surface of the light-receiving portion area and is connected to plural ones of the signal reading circuits which are provided along the one direction.

Accordingly, since a metal wiring layer equivalent to one layer of a multi-layered structure used in a related art is changed to a high-concentration impurity diffused layer, a lower profile can be achieved.

According to the above configuration and method, wirings formed of the high-concentration impurity diffused layer above the semiconductor substrate is used as global wirings. Therefore, a solid-state imaging device having a lower profile can be achieved. Thereby, multiple reflections of incident light due to the global wirings can be reduced, the incidence efficiency can be improved by a further lower profile, and it becomes possible to avoid color mixing and shading.

### BRIEF DESCRIPTION OF THE DRAWINGS

FIG. 1 is a circuit diagram of a CMOS type solid-state imaging device according to one embodiment of the present invention;

FIG. 2 is a schematic section view showing approximately two pixels of the CMOS type solid-state imaging device shown in FIG. 1;

FIG. 3 is a schematic plan view showing one unit pixel of the CMOS type solid-state imaging device shown in FIG. 1;

FIG. 4 is a schematic section view taken along a line IV-IV in FIG. 3;

FIG. 5 is a schematic section view taken along a line V-V in FIG. 3;

FIG. 6 is a schematic section view taken along a line VI-VI in FIG. 3;

FIG. 7 is a circuit diagram of a CMOS type solid-state imaging device according to another embodiment of the present invention;

FIG. 8 is a schematic plan view showing one unit pixel of the CMOS type solid-state imaging device shown in FIG. 7;

FIG. 9 is a schematic section view taken along a line IX-IX in FIG. 8;

FIG. 10 is a schematic section view taken along a line X-X in FIG. 8;

FIG. 11 is a schematic section view taken along a line XI-XI in FIG. 8;

FIG. 12 is a schematic section view taken along a line XII-XII in FIG. 8;

FIG. 13 is a view showing the entire configuration of a solid-state imaging device according to still another embodiment of the present invention;

FIG. 14 is an equivalent circuit diagram of a sense amplifier shown in FIG. 13;

FIG. 15 is a view showing global wirings of the solid-state imaging device shown in FIG. 13;

FIG. 16 is a schematic plan view showing one unit pixel of the solid-state imaging device shown in FIG. 15;

FIG. 17 is a schematic section view taken along a line XVII-XVII in FIG. 16, including a partially enlarged view;

FIG. 18 is a schematic section view taken along a line XVIII-XVIII in FIG. 16;

FIG. 19 is a schematic section view taken along a line IXX-IXX in FIG. 16;

FIG. 20 is a view for explaining a CMP process of polysilicon wiring;

FIG. 21 is a flowchart showing the major parts of a manufacturing procedure of the solid-state imaging device shown in FIG. 13;

FIG. 22A is a schematic view of a surface of a CMOS type solid-state imaging device according to a related art;

FIG. 22B is a circuit diagram of the CMOS type solid-state imaging device shown in

FIG. 22A;

FIG. 23A is a perspective view showing one unit pixel of the CMOS type solid-state imaging device shown in FIG. 22A,

FIG. 23B is a schematic section view of the one unit pixel of the CMOS type solid-state imaging device shown FIG. 23A; and

FIG. 24 is a schematic section view of a CMOS type solid-state imaging device according to a prior art, in which it is attempted to achieve a lower profile.

### DETAILED DESCRIPTION OF EMBODIMENTS OF THE INVENTION

Hereinafter, embodiments of the present invention will be described with reference to the accompanying drawings.

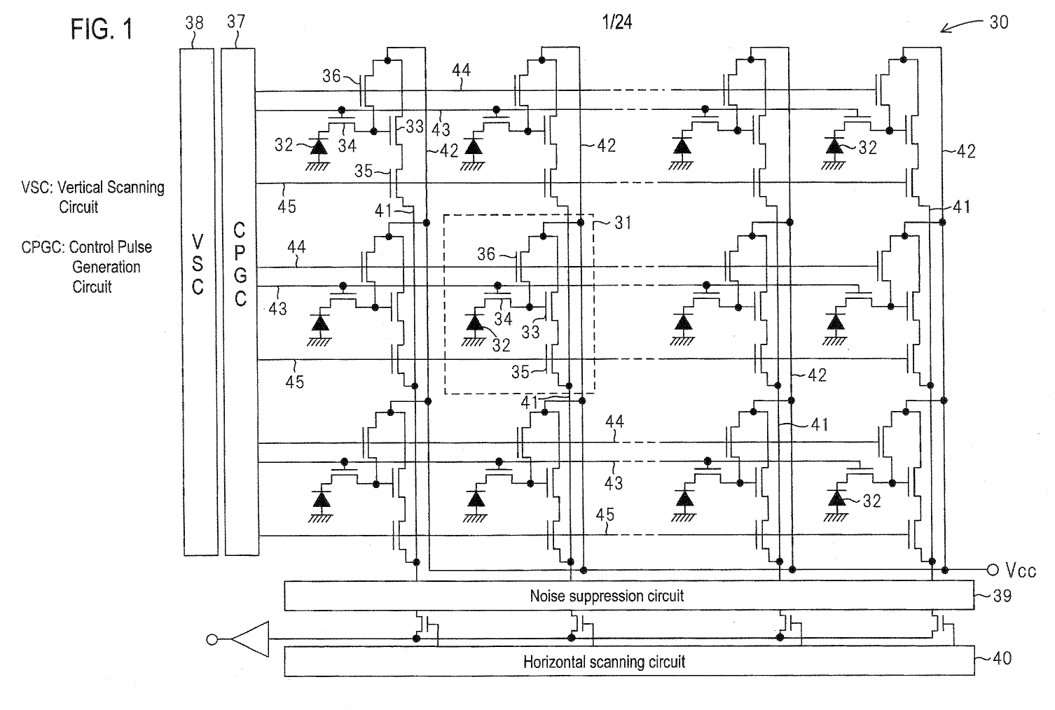

FIG. 1 is a circuit diagram of a CMOS type solid-state imaging device according to an embodiment of the invention. In the CMOS type solid-state imaging device 30 according to this embodiment, a plurality of unit pixels 31 are formed and arranged in a two-dimensional grid form (in the illustrated example, in the form of a square lattice) on a light-receiving surface (image area) of a semiconductor substrate. Each unit pixel 31 is provided with a photodiode 32 for detecting signal charges corresponding to an amount of received light and a signal reading circuit which will described later. The signal reading circuit reads captured image signals corresponding to the charges accumulated in the photodiode 32, and includes four transistors (33, 34, 35, and 36).

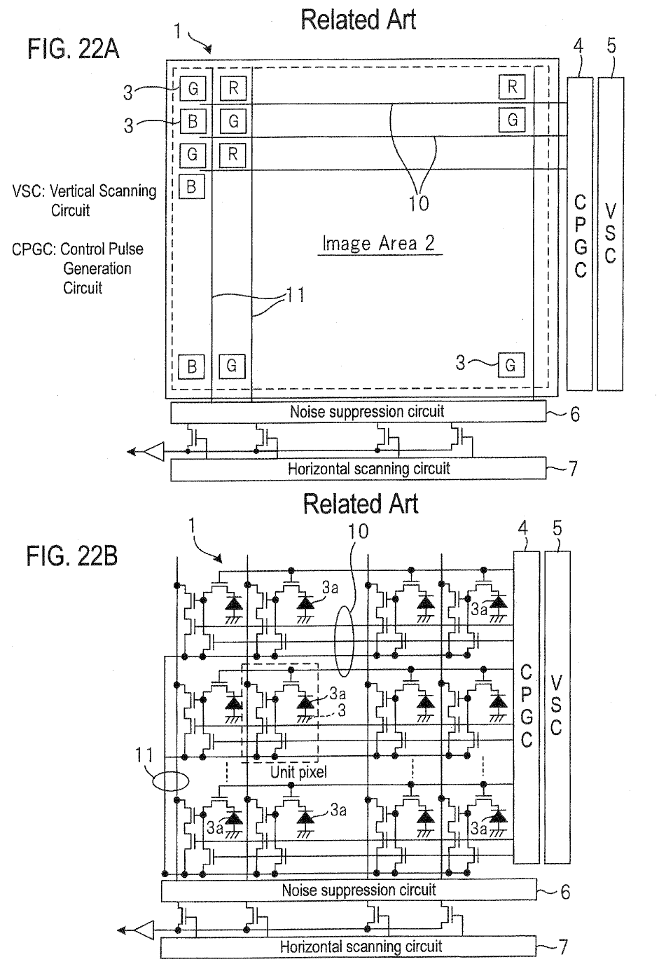

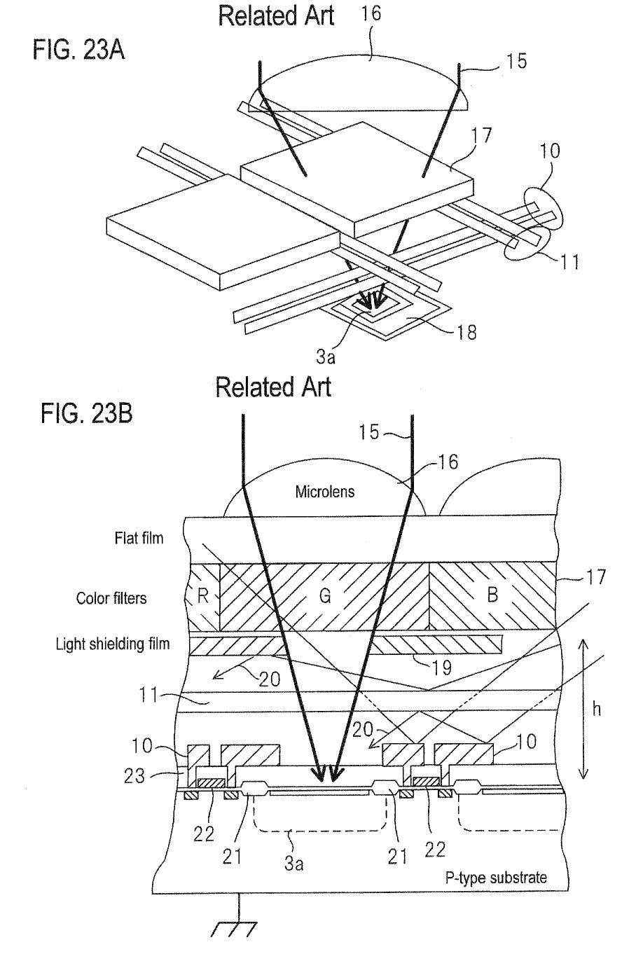

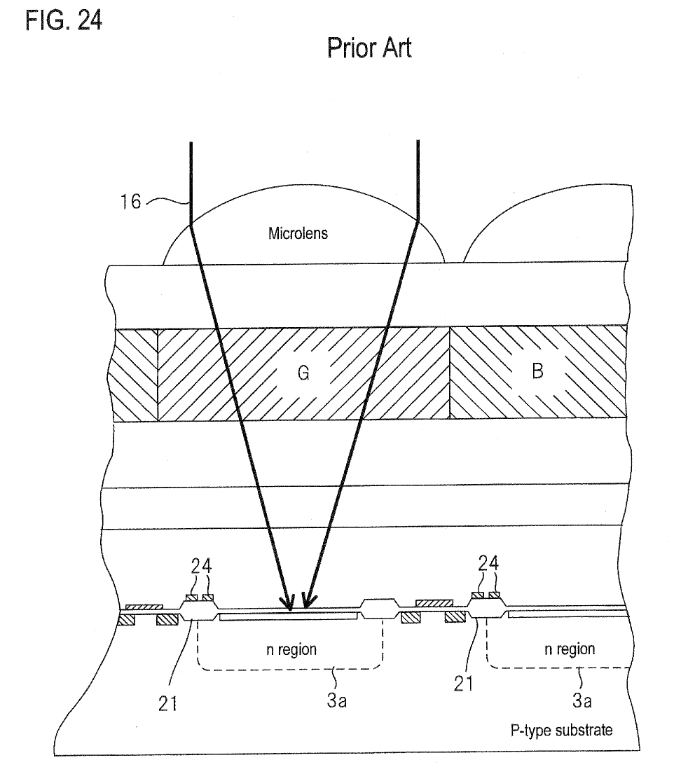

A control pulse generation circuit (CPGC) 37, a vertical scanning circuit (VSC) 38, a noise suppression circuit 39 and a horizontal scanning circuit 40 are provided in peripheral portions of the light receiving surface of a semiconductor substrate, as in the case shown in FIG. 22A.

The signal reading circuit of each unit pixel 31 includes an output transistor 33, a row reading transistor 34, a row selection transistor 35 and a rest transistor 36. The row reading transistor 34 is configured to connect a gate of the output transistor 33 and the photodiode 32 to each other and to disconnect the output transistor 33 and the photodiode 32 from each other. The row selection transistor 35 is configured to connect the output transistor 33 and an output signal line 41 to each other and to disconnect the output transistor 33 and the output signal line 41 from each other. The reset transistor 36 is configured to connect the gate of the output transistor 33 and a power source line 42 to each other and to disconnect the output transistor 33 and the power source line 42 from each other. The power source line 42 is also connected to the output transistor 33.

Of the signal reading circuits, which are formed and arranged on the light-receiving surface, the gates of the respective row reading transistors 34 on the same horizontal line are connected to a row reading (read) line 43 which is a global wiring extending from the control pulse generation circuit 37 and the vertical scanning circuit 38 in the horizontal direction. The gates of the respective reset transistors 36 on the same horizontal line are connected to a reset line 44 which is a global wiring also extending in the horizontal direction. The gates of the respective row selection transistors 35 on the same horizontal line are connected to a row selection (row select) line 45 which is a global wiring extending in the horizontal direction.

That is, in the CMOS type solid-state imaging device provided with a signal reading circuit having the four-transistor structure, three lines of the row reading (read) line 43, the reset line 44 and the row selection line 45 are required for each unit pixel row as the global wirings extending in the horizontal direction. The global wirings which extend in the vertical direction and are provided for each unit pixel column are two lines of the output signal line 41 and the power source line 42.

In such a CMOS type solid-state imaging device 30, if a read signal is applied to the row reading line 43 after the respective photodiode 32 receives light, the charges accumulated in the photodiode 32 are moved to the gate portion of the output transistor 33 via the row reading transistor 34. Then, when a selection signal is applied from the vertical scanning circuit 38 to the row selection line 45, the row selection transistor 35 becomes conductive, and the captured image signals corresponding to the amount of charges accumulated in the gate of the output transistor 33 are output from the output transistor 33 to the output signal line 41 via the row selection transistor 35.

Thereafter, as a reset signal is applied from the vertical scanning circuit 38 to the reset line 44, charges accumulated in the gate portion of the output transistor 33 is discharged into the power source line 42 via the reset transistor 36. Such a signal reading operation is sequentially carried out for the respective unit pixel rows one by one.

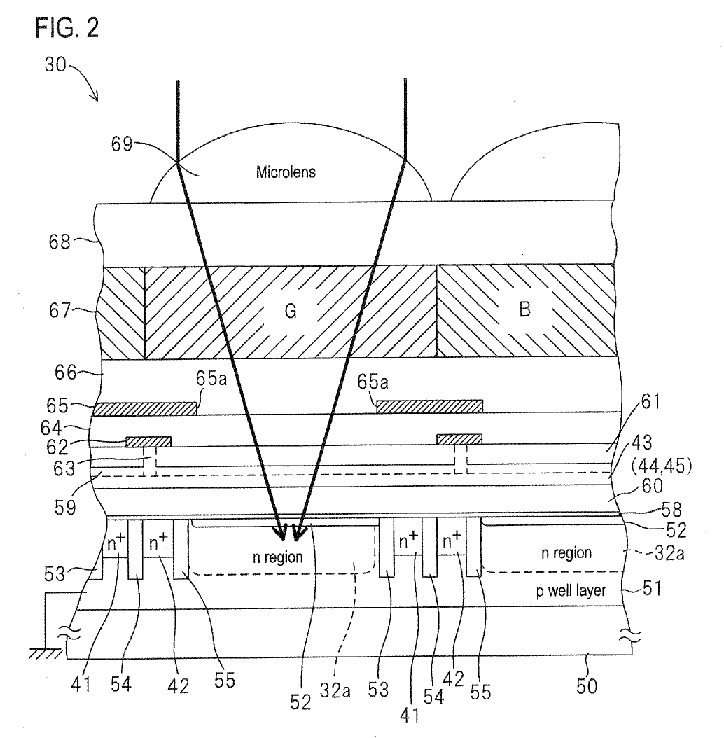

FIG. 2 is a schematic section view showing approximately two unit pixels of the CMOS type solid-state imaging device shown in FIG. 1. An n region 32a is formed on a P-well layer 51 of a n-type semiconductor substrate 50. The photodiode 32 shown in FIG. 1 is formed of pn junction between the n region 32a and the surrounding p region. A surface high-concentration p layer 52 for preventing dark current is formed on the surface of the n region 32a.

Three element isolation bands 53, 54 and 55 are spaced from each other and formed between adjacent n regions 32a. The global wiring (output signal line) 41, which is shown in FIG. 1 and is formed of a high-concentration impurity diffused layer, is formed between the element isolation bands 53 and 54, and the global wiring (power source line) 42, which is shown in FIG. 1 and is formed of a high-concentration impurity diffused layer, is formed between the element isolation bands 54 and 55. That is, in this embodiment, both of the two global wirings 41 and 42 extending in the vertical direction are formed in the semiconductor substrate 50.

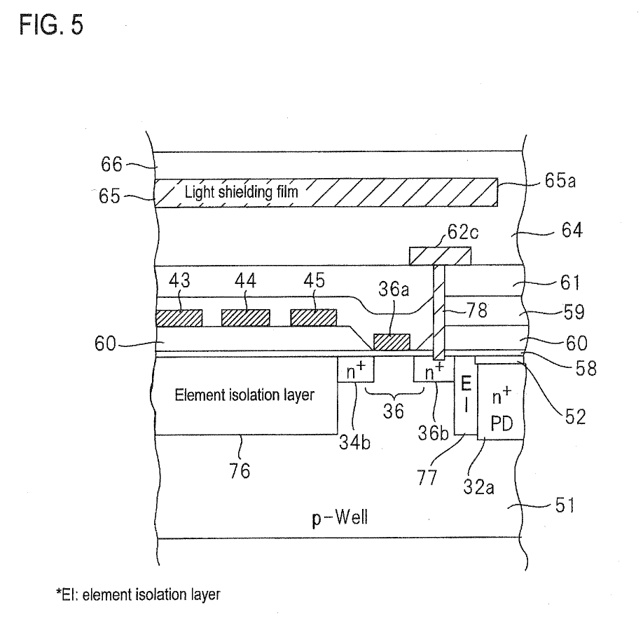

A gate insulation film 58 is formed on the outermost surface of the semiconductor substrate 50, and a transparent insulation layer 60 shown in FIG. 5 is formed thereon. The insulation layer 60 is etched in appropriate points thereof. The global wirings 43, 44, and 45, which are shown in FIG. 1 and extend in the horizontal direction, and a gate electrode (which will be described later) are formed, and a flattening layer 59 is formed thereon. That is, a stack surface formed of (i) the insulation layer 60, which becomes uneven by etching, and (ii) a polysilicon film stacked thereon is flattened by the flattening layer 59. The global wirings 43, 44 and 45 may be formed of a metallic film. Alternatively, the global wirings may be formed of a conductive polysilicon film having a slight optical reflectivity, in order to reduce irregular reflection of light. In this case, in order to further reduce the optical reflectivity, it is preferable that a surface of the conductive polysilicon film in the light incident direction may be covered with an antireflection film.

Further, a transparent interlayer insulation film 61 is formed on the flattening film 59, and an internal wiring layer 62 in the signal reading circuit is formed thereon. Since the internal wiring layer 62 occupies a small surface area, that is, produces less irregular reflection of light, the internal wiring layer 62 may be formed of a metallic film such as aluminum.

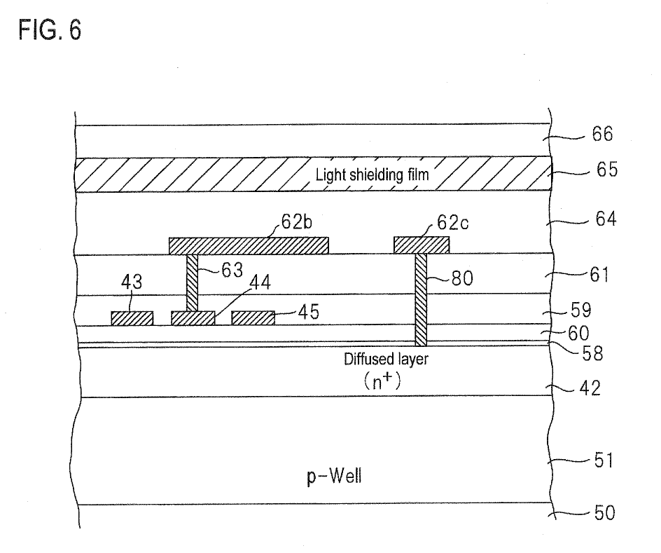

The internal wiring layer 62 is electrically connected to the global wirings 43 and 44 extending in the horizontal direction, by a contact via 63. The internal wiring layer 62 and the global wiring 42 extending in the vertical direction are electrically connected to each other by a contact via as shown in FIG. 6 (which will be described later).

After the internal wiring layer 62 is formed, a transparent flattening film 64 is formed. A light shielding film 65 formed of a metallic film, for example, aluminum, is formed thereon. The light shielding film 65 has an opening 65a formed above the n region 32a, which constitutes the photodiode 32, and the light shielding film 65 covers above the global wirings 41, 42, 43, 44 and 45, the internal wiring layer 62 and the signal reading circuit other than a region above the n region 32a, and blocks light.

A transparent flattening film 66 is stacked on an upper part of the light shielding film 65, a color filter layer 67 is provided thereon, and a microlens layer 69 is provided thereon via a transparent flattening layer 68.

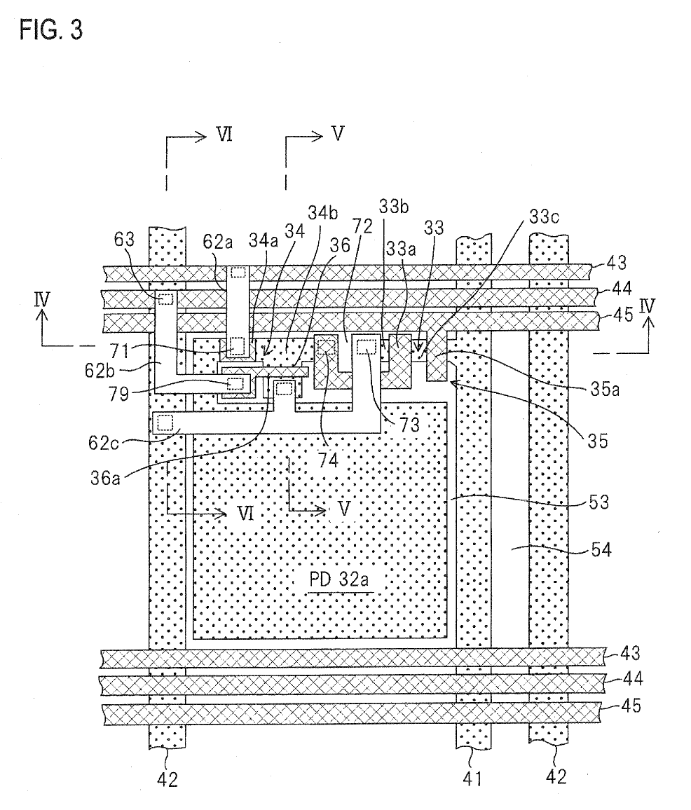

FIG. 3 is a schematic plan view of the unit pixel 31 shown in FIG. 1. The n region 32a, which constitutes the photodiode 32, is formed to be substantially rectangular. The global wirings 41 and 42 are formed on both sides of the n region 32a. The global wirings 43, 44 and 45 extending in the horizontal direction are formed along the upper and lower sides of the n region 32a.

The four MOS transistors 33, 34, 35 and 36 are formed between the upper side global wiring 45 and the n region 32a. In FIG. 3, regions having a large number of dots represent an impurity diffused layer (the n region 32a, the global wirings 41, 42 extending in the vertical direction, source regions and drain regions of the transistors 33, 34, 35 and 36), and the cross-hatched regions represent conductive polysilicon regions (the global wirings 43, 44 and 45 extending in the horizontal direction, gate electrodes 33a, 34a, 35a and 36a of the respective transistors).

In the illustrated example, there are three internal wiring layers (white portions). A first internal wiring layer 62a connects the row reading line 43 to the gate electrode 34a of the row reading transistor 34. A second internal wiring layer 62b connects the reset line 44 to the gate electrode 36a of the reset transistor 36. A third internal wiring layer 62c connects the power source line 42 to the reset transistor 36 and the output transistor 33. Dashed-line rectangular frames shown in the internal wiring 62 represent contact vias.

Also, in order to facilitate visualization of only the global wirings, (i) internal wirings for a unit pixel adjacent to the lower side of the unit pixel shown in FIG. 3 in the vertical direction and (ii) internal wirings for a unit pixel on the right side of the unit pixel shown in FIG. 3 in the horizontal direction are omitted in FIG. 3.

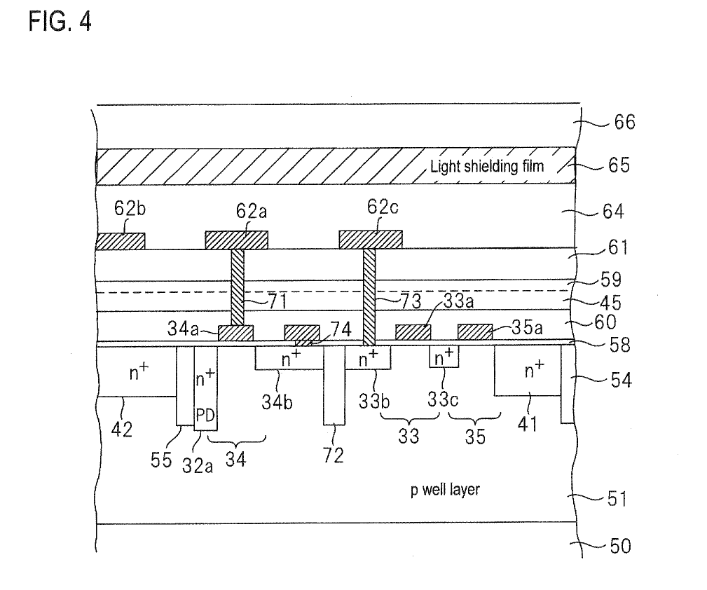

FIG. 4 is a schematic section view taken along a line IV-IV in FIG. 3. FIG. 4 shows the section of the transistors 34, 33 and 35 in the horizontal direction from the global wiring 42 on the left side of the unit pixel to the global wiring 41 on the right side of the unit pixel.

The global wiring (power source line) 42 formed of the high-concentration impurity diffused layer, the element isolation band 55 and the n region 32a extending from the photodiode 32 to the row reading transistor 34 are formed in the P-well layer 51 from the left side of the figure. An n region 34b is formed in a position slightly spaced from the n region 32a.

The gate electrode 34a made of a conductive polysilicon film is formed on the gate insulation film 58 and between the illustrated n region 32a and the n region 34b. The row reading transistor 34 is formed of the n region 32a, the gate electrode 34a and the n region 34b.

The gate electrode 34a is connected to the aluminum wiring 62a by a contact via 71. The aluminum wiring 62a is connected to the reading line 43 shown in FIG. 3. When a read signal is applied to the reading line 43, the row reading transistor 34 becomes conductive, and the charges accumulated in the photodiode 32 is moved to the n region 34b.

An element isolation band 72 is formed adjacent to the n region 34b. An n region 33b is formed adjacent to the element isolation band 72. The n region 33b is connected to the aluminum wiring 62c via a contact via 73. Thereby, the n region 33b is connected to the power source line 42 via the aluminum wiring 62c.

An n region 33c is formed slightly apart from the n region 33b. The gate electrode 33a made of a conductive polysilicon film is formed on the gate insulation film 58 and between the n region 33b and the n region 33c. The output transistor 33 is formed of n region 33b, the gate electrode 33a and the n region 33c. As shown in FIG. 3, the gate electrode 33a of the output transistor 33 is formed in a U shape so as to avoid the contact via 73, and is connected to an n region 34b by a contact via 74 on its end. Thereby, a voltage corresponding to the charges accumulated in the n region 34b is applied to the gate electrode 33a of the output transistor 33.

The gate electrode 35a made of a conductive polysilicon film is formed on the gate insulation film 58 and between the n region 33c and the global wiring (output signal line) 41, which is formed apart from the n region 33c and is made of a high-concentration impurity diffused layer. The row selection transistor 35 is formed of the n region 33c, the gate electrode 35a, and a side portion of the global wiring 41.

The row selection line 45, which is the global wiring extending in the horizontal direction, is made of a conductive polysilicon film in this embodiment. The row selection line 45 is formed on the insulation layer shown in FIG. 5, for example, the silicon oxide layer 60 by a CVD (chemical vapor deposition) process. A portion, corresponding to the gate electrode position, of the silicon oxide layer 60 is etched, and the row selection line 45 and the gate electrodes 35a, 33a, 34a, and 36a are simultaneously formed of the conductive polysilicon film. Then, the flattening film 59 to cover the gate electrode films 35, 33a, 34a and 36a are stacked.

FIG. 5 is a schematic section view taken along a line V-V in FIG. 3. FIG. 5 shows the section of the reset transistor 36 in the vertical direction. An element isolation band 76 is formed below the three global wirings 43, 44 and 45, which extend in the horizontal direction, and in the P-well layer 51. The n region 32a, which constitutes the photodiode, is formed below the light shielding film opening 65a. The reset transistor 36 is formed between an element isolation band 77 formed adjacent to the n region 32a and the element isolation band 76.

The reset transistor 36 is formed of the above-described n region 34b, which is formed adjacent to the element isolation band 76, a n region 36b which is provided to be separate from the n region 34b and to be closer to the n region 32a constituting the photodiode, and the gate electrode 36a made of a conductive polysilicon film formed on the gate insulation film 58 between both the n regions 34b and 36b. The aluminum wiring 62c is connected to the n region 36b via a contact via 78. The n region 36b is connected to the power source line 42 via the aluminum wiring 62c.

FIG. 6 is a schematic section view taken along a line VI-VI in FIG. 3. FIG. 6 shows the section in the vertical direction along the global wiring 42. The global wiring 42 formed of a high-concentration impurity diffused layer is formed along the vertical direction in the p-well layer 51. The global wiring 42 and the three global wirings 43, 44 and 45 extending in the horizontal direction are three-dimensionally crossed with the silicon oxide film 60 being provided therebetween. The aluminum wirings 62b and 62c are formed on the global wirings 43, 44 and 45 with the interlayer insulation film 61 being disposed therebetween.

The global wiring (reset line) 44 extending in the horizontal direction and the aluminum wiring 62b are connected to each other via a contact via 63. A reset signal is applied to the gate electrode 36a of the reset transistor 36 via the contact via 63, the aluminum wiring 62b, and the contact via 79 (see FIG. 3).

The power source line 42 and the aluminum 62c are connected to each other by a contact via 80. The reset transistor 36 and the output transistor 33 are connected to the power source line 42 through the contact via 80 and the aluminum wiring 62.

According to the embodiment described above, the two global wirings extending in the vertical direction are formed of the high-concentration impurity diffused layer, and the three global wirings extending in the horizontal direction are formed of the conductive polysilicon film. Only the internal wiring layer, which connects the signal reading circuit formed in each unit pixel to the global wiring is made of a metallic film. Therefore, a lower profile is achieved, and a distance between the microlens 69 and the n region 32a of the photodiode can be shortened.

Thereby, the area of the metallic wiring is reduced, and deterioration in a quality of a captured image due to multiple reflections of incident light can be reduced. The incidence efficiency into the n region 32a of the photodiode 32 can be increased. It also becomes possible to avoid color mixing and shading.

In addition, in this embodiment, such a layout is adopted that positions of the four transistors are biased toward the global wirings extending in the horizontal direction. Therefore, the area of the internal wiring formed of the metallic wiring can be made to the minimum necessary. Thereby, it becomes possible to reduce irregular reflection due to the metallic wiring.

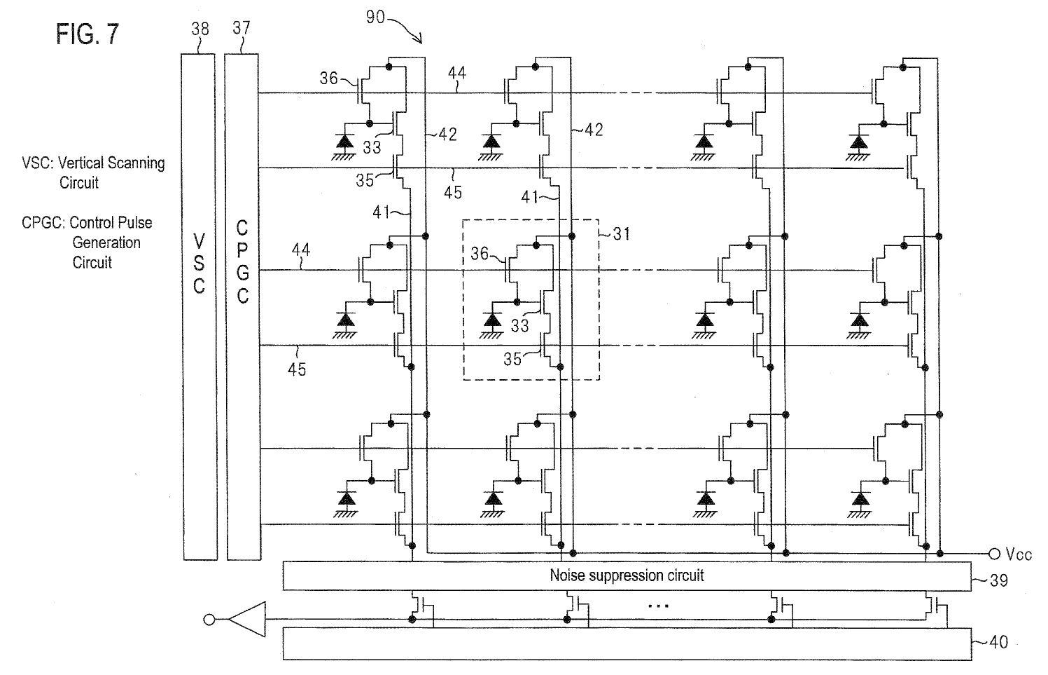

FIG. 7 is a circuit diagram of a CMOS type solid-state imaging device 90 according to another embodiment of the present invention. The CMOS type solid-state imaging device 90 of this embodiment is different from the CMOS type solid-state imaging device shown in FIG. 1 in that a signal reading circuit provided in each unit pixel according to this embodiment has a three transistor configuration. Therefore, the same components are given the same reference numerals, and description thereon will be omitted. Here, description will be given only on different portions.

Difference between the four-transistor configuration shown in FIG. 1 and the three-transistor configuration shown in FIG. 7 is that the row reading transistor 34 of the four transistors is omitted. Therefore, the read line 43 in FIG. 1 is no longer required. The global wirings extending in the horizontal direction are two lines of the reset line 44 and the row selection line 45. The global wirings extending in the vertical direction are two lines of the output signal line 41 and the power source line 42 as in FIG. 1.

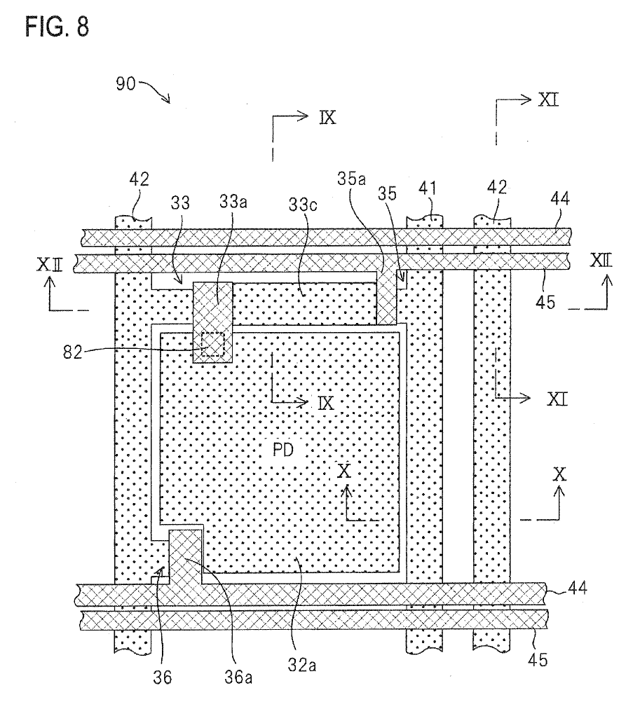

FIG. 8 is a schematic plan view of the unit pixel constituting the CMOS type solid-state imaging device 90 shown in FIG. 7. The two global wirings 41 and 42, which extend in the vertical direction and are formed of high-concentration impurity diffused layers, are formed on the right and left sides of the n region 32a constituting the photodiode 32, respectively. The two global wirings 44 and 45, which extend in the horizontal direction and are formed of a conductive polysilicon film, are provided on the upper and lower sides of the n regions 32a, respectively.

The reset transistor 36 is formed at the lower left corner of the n region 32a, which is formed in a rectangular shape in its upper plan view. The output transistor 33 is formed at the upper left corner of the n region 32a. The row selection transistor 35 is formed at the upper right corner of the n region 32a.

The gate electrode 36a of the reset transistor 36 is provided between a side portion of the n region 32a and an n region slightly extending from the power source line 42 in the unit pixel direction. The gate electrode 36a is manufactured to be integral with the reset signal line 44. When a reset signal is applied to the reset signal line 44, the charges accumulated in the n region 32a are discharged into the power source line 42 via the reset transistor 36.

The output transistor 33 is formed of the n region 33c, which is shared by the output transistor 33 and the row selection transistor 35, an n region slightly extending from the power source line 42 in the unit pixel direction, and the gate electrode 33a provided therebetween. The gate electrode 33a is formed of a conductive polysilicon film is connected to the n region 32a through a contact via 82. Thereby, a voltage equivalent to the charges accumulated in the n region 32a is applied to the gate electrode 33a.

The row selection transistor 35 is formed of the n region 33c, an n region slightly extending in the unit pixel direction from the output signal line 41, and the gate electrode 35a provided therebetween. The gate electrode 35a made of a conductive polysilicon film is formed to be integral with the global wiring (row selection line) 45 extending in the horizontal direction.

With this configuration, when a row selection signal is applied from the global wiring 45 to the gate electrode 35a, a current corresponding to the charges accumulated in the n region 32 flows between the power source line 42 and the output signal line 41 via the output transistor 33 and the row selection transistor 35, and a captured image signal is output to the output signal line 41.

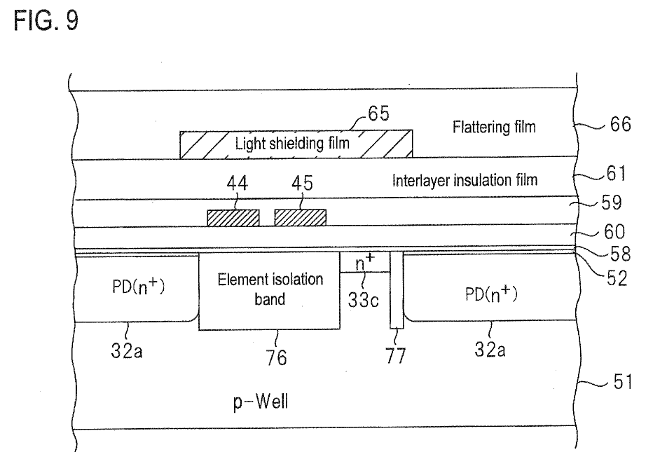

FIG. 9 is a schematic section view taken along a line IX-IX in FIG. 8. An element isolation band 76, the n region 33c, and an element isolation band 77 are provided in a p-well layer 51 between the photodiodes 32 (between the n regions 32a), which are arranged up and down in the vertical direction. The global wirings 44 and 45, which extend in the horizontal direction and are formed of the conductive polysilicon film, are provided on the silicon oxide layer 60 and above the element isolation band 76. The light shielding film 65 is provided on the interlayer insulation film 61 thereon.

When FIG. 9 is compared with FIG. 6, the flattening film 64 in FIG. 6 is not provided in FIG. 9. This is because this embodiment is configured to have a layout that does not requires the internal wiring in FIG. 6, that is, this embodiment adopts such a layout that the two global wirings are provided in each of the horizontal and vertical directions, and that it is not necessary that one of these two wirings crosses over the other of the two wirings to be connected to another portion. Accordingly, a further lower profile can be achieved than the embodiment shown in FIG. 6. Also, although the global wirings 44 and 45 in FIG. 9 are formed of the conductive polysilicon film, they may be formed of a metallic film.

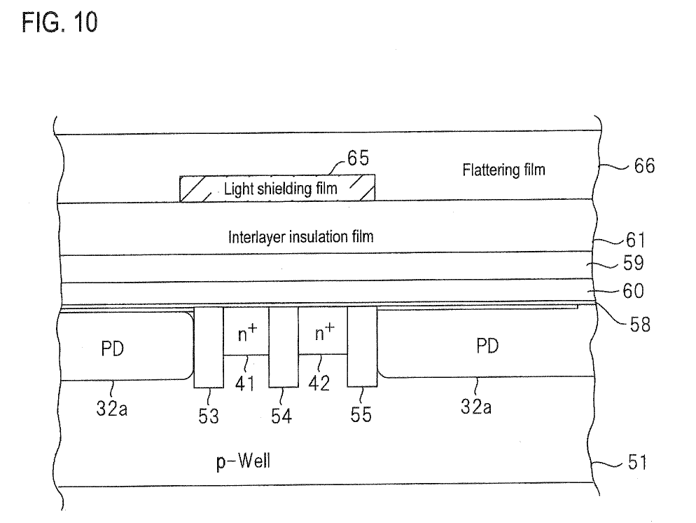

FIG. 10 is a schematic section view taken along a line X-X in FIG. 8. FIG. 10 shows the section of the global wirings 41 and 42 in the vertical direction. In this embodiment, the global wirings 41 and 42 extending in the vertical direction are formed of the high-concentration n-type impurity diffused layer.

If a resistance component is great in the global wirings extending in the vertical direction, particularly in the output signal line 41, a potential drop occurs. However, this potential drop can be reduced by increasing the cross-section areas of the global wirings and adjusting the impurity concentration to a high concentration. Thereby, practical global wirings can be obtained. If it is necessary to thin the output signal line 41 in line with advancement of multiple pixels and micronization of the CMOS type solid-state imaging device, the output signal line 41 may be made of a metal backing wiring, thereby avoiding the potential drop.

In this case, the global wiring 41 may be provided on the interlayer insulation film 61 in FIG. 9 by a metal wiring as in FIG. 6, and the flattening layer 64 may be stacked thereon.

Therefore, a lower profile the height of which is the same as that in the embodiment shown in FIG. 6 can be achieved. Also, in this case, a line width of the power source line 42 formed of the high-concentration impurity diffused layer can be doubled because the output signal line 41 is not provided. Therefore, the power source line 42 is caused to sufficiently function.

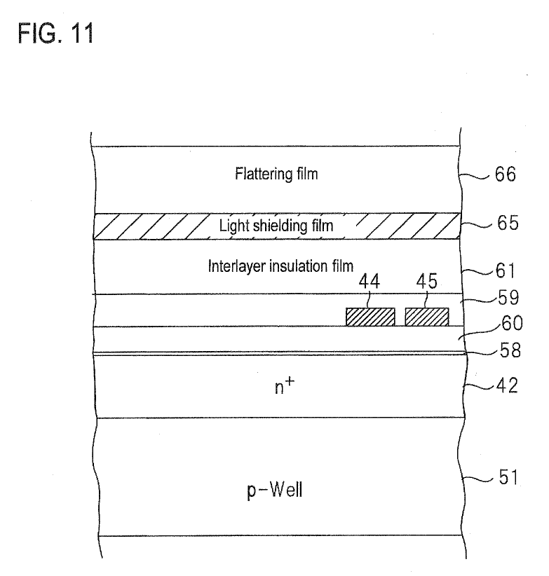

FIG. 11 is a schematic section view taken along a line XI-XI in FIG. 8. FIG. 11 shows the section of the global wiring 42 in the vertical direction. The global wiring 42, which extends in the vertical direction and is formed of the high-concentration n-type impurity diffused layer, is formed in the p-well layer 51. The silicon oxide layer 60 shown in FIG. 5 is provided between the global wirings 44 and 45, which extend in the horizontal direction. The global wirings extending in the vertical direction and those extending in the horizontal direction three-dimensionally cross with the silicon oxide layer 60 being disposed therebetween.

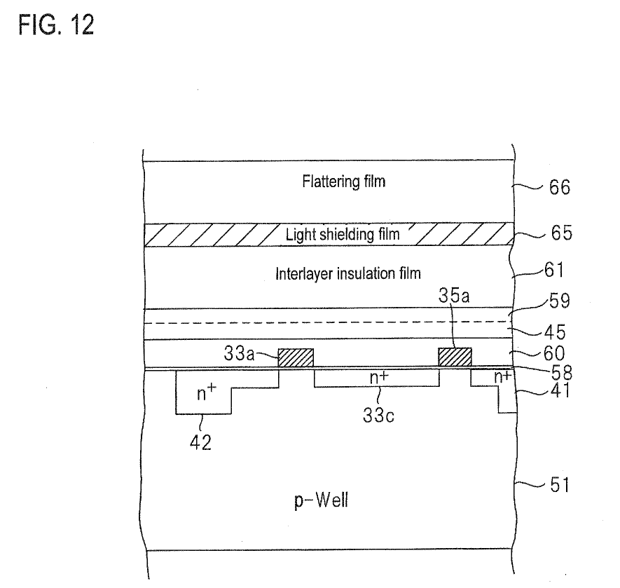

FIG. 12 is a schematic section view taken along a line XII-XII in FIG. 8. FIG. 12 shows the section of transistors 33 and 35 in the horizontal direction. The output transistor 33 is formed by providing the gate electrode 33a which is formed of the conductive polysilicon film on the gate insulation film 58 between the global wiring 42 formed of the high-concentration n-type impurity diffused layer and the n region 33c. The row selection transistor 35 is formed by providing the gate electrode 35a which is formed of the conductive polysilicon film on the gate insulation film 58 between the n region 33c and the high-concentration impurity diffused layer 41.

The gate electrode 35a is formed along with the global wiring 45 extending in the horizontal direction so as to be connected to each other by etching the insulation layer 60 in certain positions. The row selection transistor 35 becomes conductive when a row selection signal is applied to the row selection line 45.

According to the embodiment described above, the global wirings extending in the vertical direction is formed of the high-concentration impurity diffused layer in the semiconductor substrate, and the global wirings extending in the horizontal direction is made into the conductive polysilicon film formed on the surface of the semiconductor substrate with the insulation layer being disposed therebetween. Therefore, a lower profile can be achieved. Also, it becomes possible to shorten the distance between the microlens 69 and the n region 32 of the photodiode. Accordingly, the quality of a captured image can be prevented from deteriorating due to multiple reflections of the incident light. The incidence efficiency into the n region 32a can be increased, and color mixing and shading can be avoided.

Furthermore, in this embodiment, the two global wirings are provided in each of the vertical direction and the horizontal direction, and the formation positions of the three transistors are determined to be positions that don't require the internal wiring (metal wiring), unlike the embodiment shown in FIG. 3. Therefore, a further lower profile than that in the embodiment shown in FIG. 3 can be achieved.

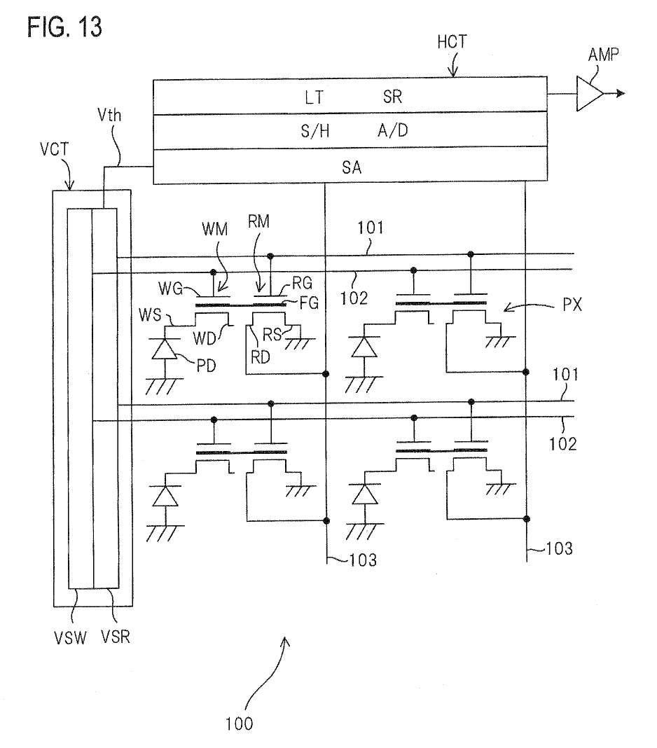

FIG. 13 is a configurational view showing a solid-state imaging device according to still another embodiment of the present invention. The basic configuration of the solid-state imaging device 100 is the same as that of the solid-state imaging device described in JP 2002-280537 A (corresponding to U.S. Pat. No. 6,781,178). Contents disclosed in JP 2002-280537 and U.S. Pat. No. 6,781,178 are incorporated herein by reference in their entirety. A plurality of unit pixels PX are formed and arranged in a two-dimensional array state in a light-receiving area of a semiconductor substrate. Although, in the illustrated example, only four unit pixels (2×2) are shown, several millions or more unit pixels PX are actually provided in the light-receiving area.

The unit pixel PX is provided with one photodiode PD serving as a photosensitive element (photoelectric conversion element), a writing memory element WM and a reading memory element RM. The writing memory element WM and the reading memory element RM constitute a signal reading circuit of the solid-state imaging device.

The writing memory element WM has a MOS transistor structure having a writing source WS connected to the photodiode PD, a floating gate FG, a writing control gate WG, and a writing drain WD.

The writing control gate WG is controlled by a writing vertical shift register VSW of a vertical control circuit VCT which will be described later. The writing memory element WM is a MOS transistor of a three-terminal structure. The writing memory element WM and the reading memory element RM share the floating gate FG are common Recorded information of the photodiode PD can be read even from the read side MOS transistor (RM).

The reading memory element RM has a MOS transistor structure having a reading source RS, a floating gate FG, a reading control gate RG, and a reading drain RD.

A voltage that monotonously changes like, for example, triangular waves, is supplied from a reading vertical shift register VSR of the vertical control circuit VCT to the reading control gate RG. A sense amplifier SA which will be described later supplies a drain voltage to the reading drain RD, and detects a threshold voltage Vth of the reading memory element based on a current value of the reading drain RD corresponding to a potential of the reading control gate RG. This threshold voltage Vth becomes a captured image signal corresponding to the amount of charges detected by the photodiode PD.

The floating gates FG of both the memory elements WM and RM of the MOS transistor structures are electrically commonly connected as described above.

The vertical control circuit VCT is formed in a peripheral portion, for example, on the left side of the light-receiving portion area in which the unit pixels are provided. A horizontal control circuit HCT is formed on the upper side of the light-receiving portion area.

The vertical control circuit VCT is provided with the vertical shift register VSW and the vertical shift register VSR. The horizontal control circuit HCT is provided with the sense amplifier SA, a sample-hold circuit S/H, an analog-digital conversion section A/D, a latch circuit LT, and a shift register SR. An output of the shift register SR is connected to an amplifier AMP.

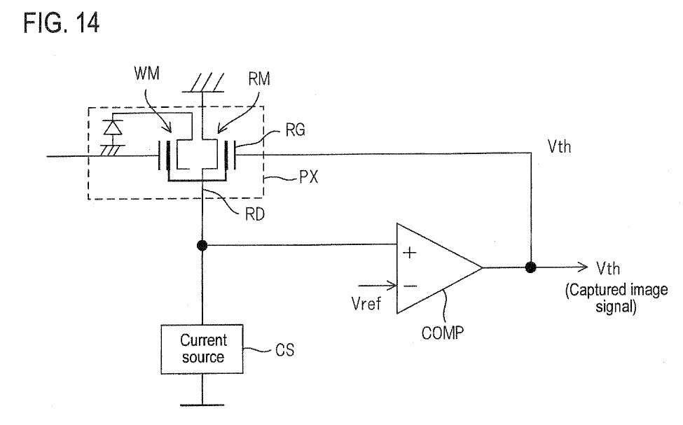

FIG. 14 shows an equivalent circuit of a threshold detection circuit of the sense amplifier SA. A reference potential Vref is supplied to an inversion input terminal of a comparator COMP. A voltage of the reading drain RD of the reading memory element RM is supplied to a non-inversion input terminal of the comparator COMP.

A current is supplied from a current source CS to the reading memory element RM. An output voltage of the comparator COMP is supplied to the reading control gate RG. The reading control gate RG is independent from the writing control gate WG, and is controlled by the reading vertical shift register VSR.

By detecting the channel current of the reading memory element RM while varying the reference potential Vref given to the comparator COMP, the threshold voltage Vth of the memory element RM is detected.

The threshold voltage (the captured image signal) detected by the sense amplifier SA is converted into digital data by having the sample-hold circuit S/H and the analog-digital conversion section A/D to process the detected threshold voltage, and the digital data is recorded in the latch circuit LT. Next, the digital data is read by the horizontal shift register SR one after another in the horizontal direction, and is output, as digital data, to an out side of the solid-state imaging device through the output buffer amplifier AMP.

When light coming from an object is incident into the solid-state imaging device having the above-described configuration, signal charges (electrons) are accumulated in the photodiode PD in response to an amount of the incident light. At least a part of the charges (electrons) corresponding to the signal charges is injected into the floating gate FG. The injection may be carried out by using the tunnel injection or the hot-electron injection phenomenon.

Since the threshold voltage (Vth) of a MOS transistor structure is varied in response to the signal charges injected into the floating gate FG, the threshold voltage (Vth) is detected by using the above-described sense amplifier SA, and is output to the outside as a captured image signal.

In the solid-state imaging device 100, as shown in FIG. 13, a reading signal line 101 for connecting the vertical shift register VSR to the respective reading control gates RG is provided for each unit pixel row as the global wiring extending in the horizontal direction (X direction), and a writing signal line 102 for connecting the vertical shift register VSW to the respective writing control gates WG is provided for each unit pixel column as the global wiring extending in the horizontal direction (X direction).

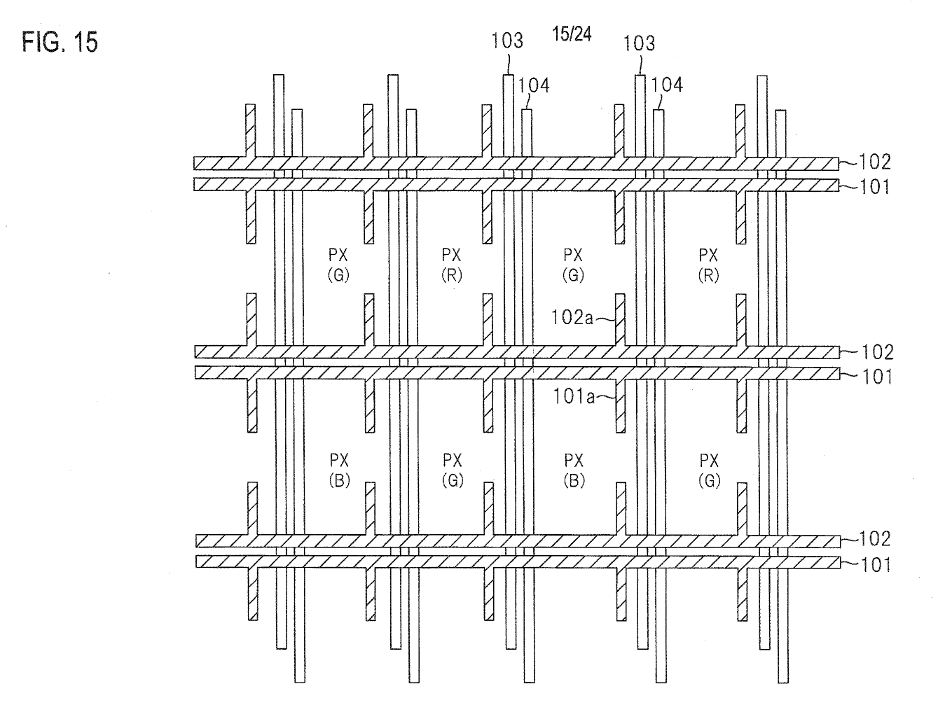

In addition, an output signal line 103 for connecting the sense amplifier SA to the respective reading drain RD is provided for each unit pixel row as the global wiring extending in the vertical direction (Y direction), and a ground line 104 (see FIG. 15, and illustration thereof is omitted in FIG. 13) for connecting the reading source RS of the reading memory elements RM to the ground is provided for each unit pixel row as the global wiring extending in the vertical direction (Y direction).

FIG. 15 is a view showing the global wirings in the solid-state imaging device 100 having the configuration shown in FIG. 13. It is noted that, in FIG. 15, only the global wirings and the gate electrodes are picked up. Two global wirings 103 and 104 extending in the vertical direction and two global wirings 101 and 102 extending in the horizontal direction are laid so that the respective unit pixels PX are partitioned into the grid form. R, G and B shown in the unit pixels represent colors (red (R), green (G) and blue (B)) of the color filters formed in the unit pixels.

Short lines 101a extending from the global wiring 101 in a direction toward the interior of the respective unit pixels PX are gate lines serving as the reading control gates RG provided in the unit pixels PX. Also, short lines 102a extending from the global wirings 102 in a direction toward the interior of the respective unit pixels PX are gate lines serving as the writing control gates WG provided in the unit pixels PX.

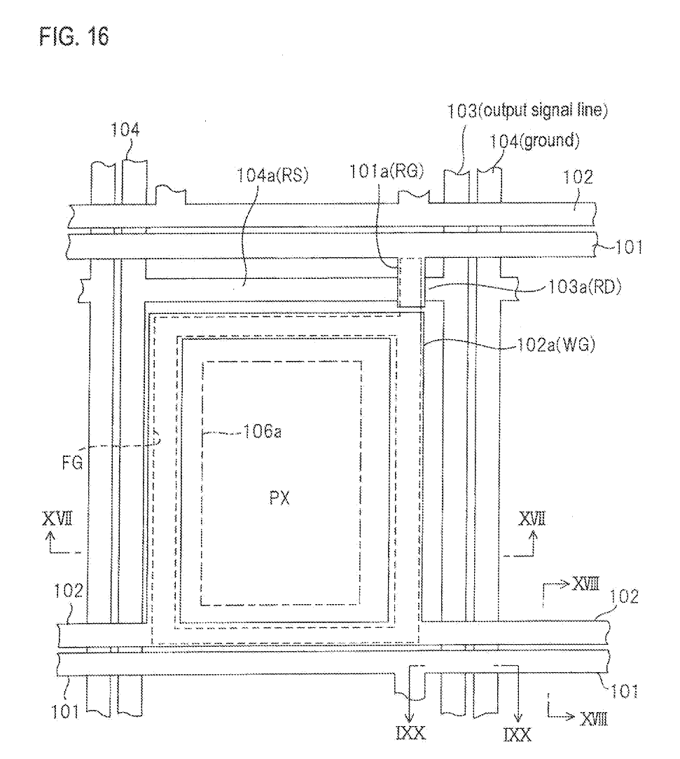

FIG. 15 shows the gate lines 102a by the short lines. However, the shape of each gate line 102a is optional. In an embodiment described later (FIG. 16), the gate lines 102a are formed in a U shape.

FIG. 16 is a schematic plan view showing one unit pixel PX shown in FIG. 15. A rectangular area defined by the two global wirings 101 and 102 extending in the horizontal direction and the two global wirings 103 and 104 extending in the vertical direction corresponds to one unit pixel PX.

In this embodiment, the global wirings 103 and 104 extending in the vertical direction are formed of a high-concentration impurity diffused layer formed on a surface of a semiconductor substrate, and the global wirings 101 and 102 extending in the horizontal direction are formed of a polysilicon film which have conductivity and is laid on the surface of the semiconductor substrate. Since the global wirings 103 and 104 are formed so as to be buried in the semiconductor substrate, and the global wirings 101 and 102 formed on a light incident side of the semiconductor substrate are formed of the polysilicon film made of a low reflection conductive material. Thereby, multiple reflections can be prevented.

The two polysilicon wirings 101 and 102 may be formed so as to be spaced from each other on the same plane by a lithography method. Alternatively, the wirings 101 and 102 may be electrically insulated from each other by an insulation film (for example, polysilicon oxide film). At least a part of the wirings 101 and 102 overlaps each other (multi-layered polysilicon method).

The short gate line 101a extending from the global wiring 101 corresponds to the control gate RG shown in FIG. 13. The U-shaped gate line 102a (which is a totally closed rectangular shape since the U-shaped opening end is connected to the wiring 102) extending from the global wiring 102 corresponds to the control gate WG shown in FIG. 13.

The floating gate FG is formed in a portion (area shown by dashed lines in FIG. 16) bridging both the control gates RG and WG. A part of the floating gate FG other than a portion extending in the direction of the wiring 101 is formed so that it encloses the entire circumference of an n region 111 (which will be described later) constituting the unit pixel PX and that it is adjacent to a boundary portion of the n region 111.

The global wiring 104 is a ground line. A line 104a which extends from the ground line 104 to an end of the control gate RG and is formed of a high-concentration impurity diffused layer serves as the reading source RS shown in FIG. 13. A line 103a which extends from the signal output line 103 to the end of the control gate RG and is formed of a high-concentration impurity diffused layer serves as the reading drain (RD) shown in FIG. 13. The rectangular frame 106a enclosed by an alternate long and short dashed line in the figure is A light shielding film opening.

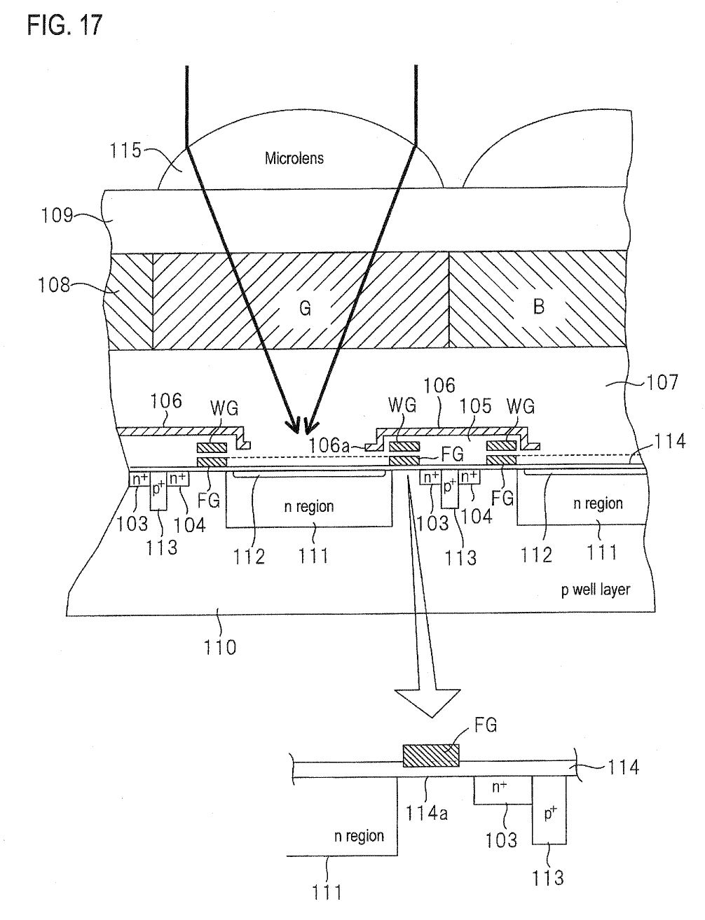

FIG. 17 is a schematic section view taken along a line XVII-XVII in FIG. 16. The photodiode PD, which is a photosensitive element, is provided by forming the n region 111 on a surface portion of a p-type semiconductor substrate 110 or on a surface portion of a p-well layer 110 formed on an n-type semiconductor substrate. A high-concentration p-type surface layer 112 that suppresses a dark current is formed on the surface portion of the n region 111.

An element isolation region 113 is formed between the n regions 111 which are adjacent to each other in the horizontal direction. The global wirings 103 and 104 formed of a high-concentration impurity diffused layer are formed on both sides of the element isolation region 113. The element isolation region 113 may be STI (Shallow Trench Isolation).

A surface thermal oxide film 114 is formed on the surface of the semiconductor substrate 110. The floating gate FG adjacent to a boundary of the n region 111 is formed on the surface thermal oxide film 114 between the wiring layers 103, 104 and the n region 111. The floating gate FG is formed of a conductive polysilicon film as in the global wiring 102.

The oxide film 114a under the floating gate FG is formed to be thinner than the surface thermal oxide film 114 in the other portions as shown in an enlarged view in the lower portion of FIG. 17, and is formed into a tunnel oxide film having 100 Å in thickness or less. Therefore, electrons accumulated in the n region 111 can be efficiently injected into the floating gate FG.

Further, FIG. 17 shows that the oxide film under the floating gate FG in one portion is thinned. However, the oxide film under the floating gate FG located in any portion is formed into a tunnel oxide film.

The control gate WG is formed above the floating gate FG with an insulation layer being located therebetween. The control gate WG is formed of a polysilicon film simultaneously with the global wiring 102. A light shielding film 106 made of a tungsten film, which is excellent in light shielding property, is formed above the control gate WG with a flattening protection film 105 being located therebetween. The light shielding film opening 106a is provided in the light shielding film 106 above the n region 111.

A flattening film 107 is formed on the light shielding film 106, and a color filter layer 108 is formed thereon, and a microlens 115 is stacked further thereon through a flattening film 109.

In the solid-state imaging device 100 according to this embodiment, the wirings formed of the high-concentration impurity diffused layer and the wirings formed of the conductive polysilicon film are used as the global wirings, a lower profile can be achieved, that is, the height to the microlens 115 when observed from the n region 111 of the photodiode (PD) can be made lower. It is possible to avoid multiple reflections, color mixing and shading due to the global wirings made of the multi-layered metal wirings. Thereby, the incidence efficiency can be improved.

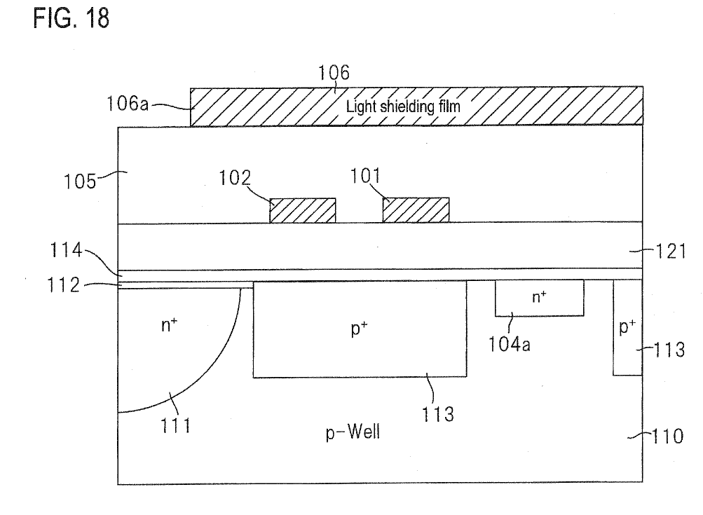

FIG. 18 is a schematic section view taken along a line XVIII-XVIII in FIG. 16, and is a schematic section view of the global wirings 101 and 102 in the horizontal direction. The p-well layer 110 of the semiconductor substrate is separated by the high-concentration p-type element isolation regions 113 in a portion between adjacent unit pixels and in appropriate portions. The oxide film 114 is formed on the surface of the p-well layer 110, and a transparent silicon oxide layer 121 is formed thereon. The global wirings 101 and 102, which extend in the horizontal direction and are formed of a conductive polysilicon, are laid on the silicon oxide film 121. The light shielding film 106 is stacked thereon with the flattening film 105 being disposed between the light shielding film 106 and the silicon oxide film 121.

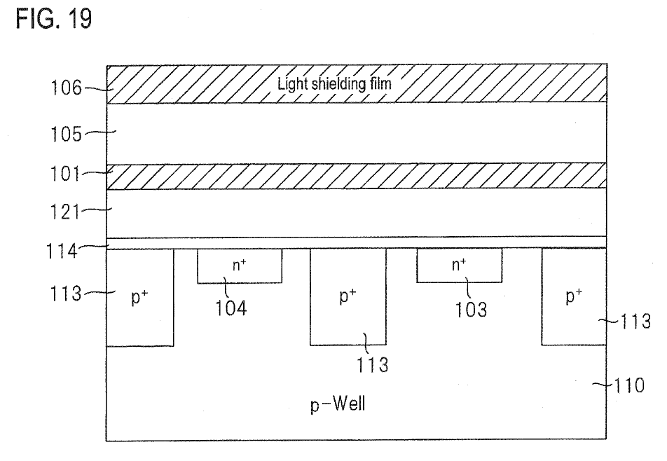

FIG. 19 is a schematic section view taken along a line IXX-IXX in FIG. 16. FIG. 19 schematically shows a place at which the global wirings 103 and 104 extending in the vertical direction cross the global wirings 101 and 102 extending in the horizontal direction.

The two global wirings 103 and 104 formed of the high-concentration n-type impurity diffused layer and extending in the vertical direction are spaced from each other and formed in the P-well layer 110. The two global wirings 103 and 104 are isolated by the high-concentration p-type element isolation region 113, which is located therebetween. The oxide film 114 is formed on the surface of the semiconductor substrate, and the transparent silicon oxide film 121 is formed thereon. The global wiring 101 (102) formed of the conductive polysilicon film and extending in the horizontal direction is laid further thereon. The light shielding film 106 is stacked still further thereon with the flattening film 105 being disposed between the light shielding film 106 and the global wiring 101 (102).

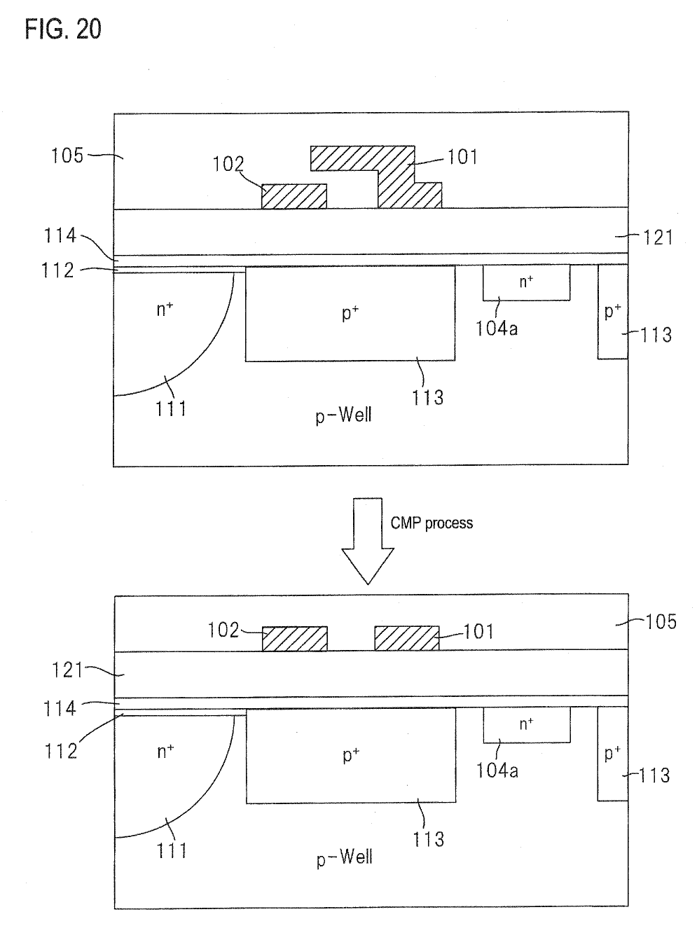

FIG. 20 is a section view showing global wirings formed of a polysilicon film according to another embodiment. The global wirings 101 and 102 may be formed of a two-layered polysilicon film having an overlapped portion as shown in an upper portion of FIG. 20. However, as shown in a lower portion of FIG. 20, if the wirings 101 and 102 (shown in the upper portion in FIG. 20) formed of the two-layered polysilicon film are subjected to a process by which the overlapped portion thereof is flattened by the CMP (Chemical Mechanical Polishing) process, the flattening protection film 105 is only thinly stacked. This is preferable because the entirety of the profile can be made further lower.

The global wiring formed of the polysilicon film may be doped a polysilicon having, for example, phosphate (P), arsenic (As), boron (B) doped at a high concentration. Alternatively, the global wiring may be silicide and salicide (self-aligned silicide) in which various types of metals such as titanium (Ti) and tungsten (W) are combined with silicon.

Thus, one of (i) the global wirings extending in the vertical direction or (ii) the global wirings extending in the horizontal direction is formed of the high-concentration impurity diffused layer formed on the surface portion of the semiconductor substrate. Therefore, one layer of the aluminum wirings formed of the multi-layered structure can be omitted. Thereby, a lower profile can be achieved. Further, if the other global wiring is formed of the polysilicon film, one layer of the aluminum wirings can be omitted. Thereby, a further lower profile can be achieved.

That is, the following effects are obtained with the solid-state imaging device according to the embodiments described above.

(1) The incidence angle dependence of the CMOS type solid-state imaging device is improved. The CMOS type solid-state imaging device can be combined with a short-focus optical system and/or a low F-number optical system. Therefore, an imaging module can be thinned.
(2) A tungsten light shielding film may be used in the CMOS type solid-state imaging device. Therefore, leakage of light to adjacent pixels, and a problem (pinhole, etc.) caused by an aluminum light shielding film can be solved.
(3) An image sensor that can capture a high-quality image can be manufactured without the normal CMOS process being modified greatly.

Further, the following effects can be achieved.

(4) Any contact portion to outside wirings is no longer required in the pixel areas. Therefore, it becomes possible to further minimize the pixels and to enlarge the area of the photodiodes (that is, high sensitivity and wide dynamic range can be obtained).
(5) The solid-state imaging device of the above embodiment is compatible with the shortened focal length of microlenses, which is caused by miniaturization of pixels.
(6) It becomes easy to compensate for a lowering in the sensitivity in the peripheral portions of the image sensor by so-called “positional shift of microlenses/color filters (the positional shift amount can be reduced).

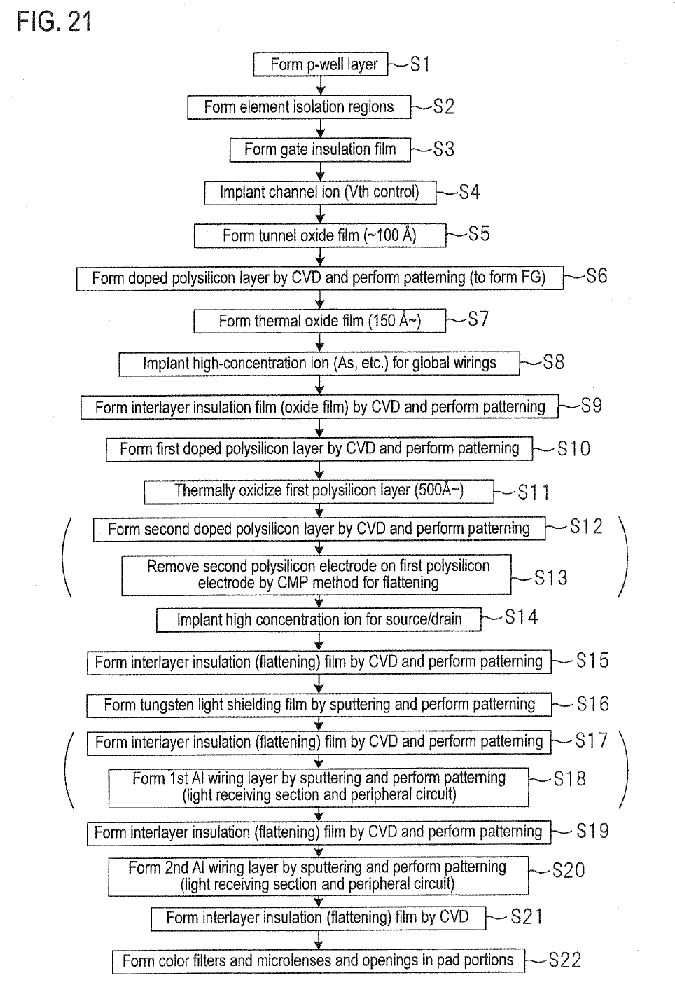

FIG. 21 is a flowchart showing the major parts of a manufacturing procedure of the solid-state imaging device described above. First, the p-well layer 110 is formed in the semiconductor substrate (step S1). In step S2, the n regions 111 shown in FIG. 17, etc., are formed and then, the element isolation regions 113 are formed. The surface oxide film 114 is formed by oxidizing the surface of the semiconductor substrate (Step S3).

In the next step S4, channel ions for the MOS structure transistor constituting the signal reading circuit are implanted. In the next step S5, the tunnel oxide film 114a having about 100 Å, which is shown in the lower portion enlarged view of FIG. 17, is formed.

Then, the floating gate FG is formed by stacking a doped polysilicon layer by the CVD (chemical vapor deposition) process and patterning it (step S6). The surface of the floating gate FG is thermally oxidized to make the thickness of the oxide film to be 150 Å or more (step S7). Thereafter, high-concentration ions such as arsenic (As), etc., are implanted to form the global wirings 103 and 104 (see FIG. 17) in step S8.

In the next Step S9, the silicon oxide film 121 in FIGS. 18 and 19 is formed by forming an interlayer insulation film (oxide film) by the CVD process and patterning it. In step S10, the global wirings 102 shown in the upper portion of FIG. 20 is formed by forming the first doped polysilicon layers by the CVD process and patterning it. Next, the global wirings 102 are thermally oxidized (step S11), and the global wirings 101 shown in the upper portion of FIG. 20 are formed by forming the second doped polysilicon layers by the CVD process and patterning it (step S12). In the next step S13, the global wirings 101 are brought into the state shown in the lower portion in FIG. 20 by flattening the global wirings 101 by the CMP method.

If the global wirings 101 and 102 of the single-layered structure shown in FIG. 18 are patterned from the first doped polysilicon film without using the CMP method, steps S12 and s13 are no longer required. In the next step S14, high-concentration ions are implanted into the portions where the sources of the MOS structure transistors that constitute the signal reading circuits and the portions where the drains of the MOS structure transistors are formed, thereby forming the drains of the MOS structure transistors.

In the next step S15, the interlayer insulation film 105 shown in FIGS. 17, 18 and 19 is formed by the CVD process and patterning it. Then, the openings 106a are formed by sputtering and patterning the tungsten light shielding film formed on the interlayer insulation film 105 (step S16).

Next, if it becomes necessary to form aluminum wirings equivalent to one layer above the semiconductor substrate, an interlayer insulation film is formed by the CVD and patterned in step S17, and the aluminum wiring layer is formed by sputtering and patterning (step S18).

In addition, in the embodiment shown in FIGS. 16 and 17, steps S17 and S18 are no longer required because of the structure, which does not require the aluminum wiring layer. However, the aluminum wiring layer may be formed in the steps S17 and S18 in the case of the layout structure, which requires the aluminum wirings as the internal wirings.

In the next step S19, the interlayer insulation films are formed at appropriate positions. Aluminum wirings such as the peripheral circuits (VCT, HCT, AMP, etc., shown in FIG. 13) are formed (step S20). The interlayer insulation film 107 (see FIG. 17) is formed (in step S21). Thereafter, in step S22, the color filter layer 108, the microlenses 115, etc., are formed.

Also, in the respective embodiments described above, the global wirings are described using the words “vertical direction” and “horizontal direction.” However, the “vertical” and “horizontal” only mean “one direction” along the surface of the light-receiving portion area and a “direction orthogonal to the one direction”, respectively.

As described above, according to the embodiments of the present invention, a solid-state imaging device includes a plurality of photosensitive elements, signal reading circuit and a first type wiring. The plurality of photosensitive elements are arranged in a two-dimensional array state in a light-receiving portion area of a semiconductor substrate. The signal reading circuits are formed so as to correspond to the respective photosensitive elements. Each signal reading circuit detects a captured image signal corresponding to signal charges of the corresponding one of the photosensitive elements. The signal charges are accumulated in response to an amount of light which come from an object and is received by the corresponding one of the photosensitive elements. The first type wiring is formed of a high-concentration impurity diffused layer. The first type wiring is formed in one direction along a surface of the light-receiving portion area and is connected to plural ones of the signal reading circuits which are arranged along the one direction. Thereby, the solid-state imaging device having a lower profile can be achieved. Also, it becomes possible to shorten a distance between the microlenses and the photodiodes.

Also, the solid-state imaging device described above may further include the second type wiring formed of the conductive polysilicon film. The second type wiring crosses the first type wiring above a surface of the semiconductor substrate with an insulation layer being disposed between the first and second type wirings. The second type wiring is connected to plural ones of the signal reading circuits which are arranged along a crossing direction in which the second type wiring extends. Thereby, it becomes possible to achieve a further lower profile.

In addition, in the above described solid-state imaging device, the first type wiring may include a power source line and an output signal line. The power source line supplies a power voltage to the plural ones of the signal reading circuits, which are arranged along the one direction. The output signal line outputs the captured image signals from the plural ones of the signal reading circuits, which are arranged along the one direction. Thereby, the solid-state imaging device is applicable to a CMOS type image sensor.

Further, in the above described solid-state imaging device, the second type wiring may include a control line connected to input terminals of the plural ones of the signal reading circuits which are arranged along the crossing direction. Thereby, the solid-state imaging device is applicable to a CMOS type image sensor.

Still further, in the above described solid-state imaging device, each signal reading circuit may include a writing memory element of a MOS transistor structure and a reading memory element of the MOS transistor structure. The writing memory element and the reading memory element of each signal reading circuit share a floating gate into which the accumulated signal charges of the corresponding one of the photosensitive elements are injected. Thereby, the solid-state imaging device is applicable to a floating gate type solid-state imaging device.

In addition, in the above described solid-state imaging device, a sense amplifier may detect a threshold voltage at which a drain current of the reading memory element of each signal reading circuit begins to flow, as the captured image signal. Thereby, the solid-state imaging device is applicable to the floating gate type solid-state imaging device.

Also, in the above described solid-state imaging device, the first type wiring may include a ground line and an output signal line. The ground line connects the plural ones of the signal reading circuits, which are arranged along the one direction, to a ground. The output signal line outputs the captured image signals from the plural ones of the signal reading circuits, which are arranged along the one direction. Thereby, the solid-state imaging device is applicable to the floating gate type solid-state imaging device.

In the above described solid-state imaging device, each signal reading circuit may include a writing memory element of a MOS transistor structure and a reading memory element of the MOS transistor structure. The writing memory element and the reading memory element of each signal reading circuit share a floating gate into which the accumulated signal charges of the corresponding one of the photosensitive elements are injected. The second type wiring may be connected to control gates of the plural ones of the signal reading circuits which are arranged along the crossing direction. Thereby, the solid-state imaging device is applicable to the floating gate type solid-state imaging device.

Also, in the above described solid-state imaging device, wirings that connect the first type wiring or the second type wiring to the signal reading circuits may be formed of a metallic film. Thereby, the degree of freedom of wiring can be improved, and the design of the solid-state imaging device can be facilitated.

Further, in the above described solid-state imaging device, wirings that connect the first type wiring to terminals of MOS transistors constituting the plural ones of the signal reading circuits, which are arranged along the one direction, may be formed of a high-concentration impurity diffused layer that is manufactured in a same manufacturing process as the first type wiring. Wirings that connect the second type wiring to terminals of MOS transistors constituting the plural ones of the signal reading circuits, which are arranged along the crossing direction, may be formed of a conductive polysilicon film manufactured in a same production process as the second type wiring. Thereby, a lower profile equivalent to a CCD type image sensor can be achieved.

Also, a method for manufacturing a solid-state imaging device includes: forming and arranging a plurality of photosensitive elements in a two-dimensional array state in a light-receiving portion area of a semiconductor substrate; forming signal reading circuits so as to correspond to the respective photosensitive elements, each signal reading circuit being formed to detect a captured image signal corresponding to signal charges of the corresponding one of the photosensitive elements, the signal charges being accumulated in response to an amount of light which come from an object and is received by the corresponding one of the photosensitive elements; and forming a first type wiring which is formed of a high-concentration impurity diffused layer, extend in one direction along a surface of the light-receiving portion area and is connected to plural ones of the signal reading circuits which are provided along the one direction. Thereby, a solid-state imaging device of a lower profile can be achieved.

The solid-state imaging device according to the exemplary embodiments of the present invention can achieve a lower profile. Therefore, the light incidence efficiency into respective pixels (photodiodes) can be increased, and color mixing and shading can be prevented from occurring. Furthermore, the solid-state imaging device is useful if it is incorporated in an imaging apparatus such as a digital camera and a mobile telephone set, etc.

What is claimed is:

1. A solid-state imaging device comprising:
a plurality of photosensitive elements that are arranged in a two-dimensional array state in a light-receiving portion area of a semiconductor substrate;
signal reading circuits that are formed so as to correspond to the respective photosensitive elements, wherein each signal reading circuit detects a captured image signal corresponding to signal charges of the corresponding one of the photosensitive elements, the signal charges being accumulated in response to an amount of light which come from an object and is received by the corresponding one of the photosensitive elements; and
a first type wiring that is formed of a high-concentration impurity diffused layer, wherein the first type wiring is formed in one direction along a surface of the light-receiving portion area and is connected to plural ones of the signal reading circuits which are arranged along the one direction.

2. The solid-state imaging device according to claim 1, further comprising:
a second type wiring that is formed of a conductive polysilicon film, wherein
the second type wiring crosses the first type wiring above a surface of the semiconductor substrate with an insulation layer being disposed between the first and second type wirings, and
the second type wiring is connected to plural ones of the signal reading circuits which are arranged along a crossing direction in which the second type wiring extends.

3. The solid-state imaging device according to claim 1, wherein
the first type wiring includes
a power source line that supplies a power voltage to the plural ones of the signal reading circuits, which are arranged along the one direction, and
an output signal line that outputs the captured image signals from the plural ones of the signal reading circuits, which are arranged along the one direction.

4. The solid-state imaging device according to claim 2, wherein
the first type wiring includes
a power source line that supplies a power voltage to the plural ones of the signal reading circuits, which are arranged along the one direction, and
an output signal line that outputs the captured image signals from the plural ones of the signal reading circuits, which are arranged along the one direction.

5. The solid-state imaging device according to claim 2, wherein the second type wiring includes a control line connected to input terminals of the plural ones of the signal reading circuits which are arranged along the crossing direction.

6. The solid-state imaging device according to claim 4, wherein the second type wiring includes a control line connected to input terminals of the plural ones of the signal reading circuits which are arranged along the crossing direction.

7. The solid-state imaging device according to claim 1, wherein
each signal reading circuit includes
a writing memory element of a MOS transistor structure, and
a reading memory element of the MOS transistor structure, and
the writing memory element and the reading memory element of each signal reading circuit share a floating gate into which the accumulated signal charges of the corresponding one of the photosensitive elements are injected.

8. The solid-state imaging device according to claim 2, wherein
each signal reading circuit includes
a writing memory element of a MOS transistor structure, and
a reading memory element of the MOS transistor structure, and
the writing memory element and the reading memory element of each signal reading circuit share a floating gate into which the accumulated signal charges of the corresponding one of the photosensitive elements are injected.

9. The solid-state imaging device according to claim 7, further comprising:
a sense amplifier that detects a threshold voltage at which a drain current of the reading memory element of each signal reading circuit begins to flow, as the captured image signal.

10. The solid-state imaging device according to claim 8, further comprising:
a sense amplifier that detects a threshold voltage at which a drain current of the reading memory element of each signal reading circuit begins to flow, as the captured image signal.

11. The solid-state imaging device according to claim 7, wherein
the first type wiring includes
a ground line that connects the plural ones of the signal reading circuits, which are arranged along the one direction, to a ground, and
an output signal line that outputs the captured image signals from the plural ones of the signal reading circuits, which are arranged along the one direction.

12. The solid-state imaging device according to claim 8, wherein
the first type wiring includes
a ground line that connects the plural ones of the signal reading circuits, which are arranged along the one direction, to a ground, and
an output signal line that outputs the captured image signals from the plural ones of the signal reading circuits, which are arranged along the one direction.

13. The solid-state imaging device according to claim 9, wherein
the first type wiring includes
a ground line that connects the plural ones of the signal reading circuits, which are arranged along the one direction, to a ground, and
an output signal line that outputs the captured image signals from the plural ones of the signal reading circuits, which are arranged along the one direction.

14. The solid-state imaging device according to claim 10, wherein
the first type wiring includes
a ground line that connects the plural ones of the signal reading circuits, which are arranged along the one direction, to a ground, and
an output signal line that outputs the captured image signals from the plural ones of the signal reading circuits, which are arranged along the one direction.

15. The solid-state imaging device according to claim 2, wherein
each signal reading circuit includes
a writing memory element of a MOS transistor structure, and
a reading memory element of the MOS transistor structure,
the writing memory element and the reading memory element of each signal reading circuit share a floating gate into which the accumulated signal charges of the corresponding one of the photosensitive elements are injected, and
the second type wiring is connected to control gates of the plural ones of the signal reading circuits which are arranged along the crossing direction.

16. The solid-state imaging device according to claim 2, wherein wirings that connect the first type wiring or the second type wiring to the signal reading circuits are formed of a metallic film.

17. The solid-state imaging device according to claim 15, wherein wirings that connect the first type wiring or the second type wiring to the signal reading circuits are formed of a metallic film.

18. The solid-state imaging device according to claim 2, wherein
wirings that connect the first type wiring to terminals of MOS transistors constituting the plural ones of the signal reading circuits, which are arranged along the one direction, are formed of a high-concentration impurity diffused layer that is manufactured in a same manufacturing process as the first type wiring, and
wirings that connect the second type wiring to terminals of MOS transistors constituting the plural ones of the signal reading circuits, which are arranged along the crossing direction, are formed of a conductive polysilicon film manufactured in a same production process as the second type wiring.

19. The solid-state imaging device according to claim 15, wherein
wirings that connect the first type wiring to terminals of MOS transistors constituting the plural ones of the signal reading circuits, which are arranged along the one direction are formed of a high-concentration impurity diffused layer that is manufactured in a same manufacturing process as the first type wiring, and
wirings that connect the second type wiring to terminals of MOS transistors constituting the plural ones of the signal reading circuits, which are arranged along the crossing direction are formed of a conductive polysilicon film manufactured in a same production process as the second type wiring.

20. A method for manufacturing a solid-state imaging device, the method comprising
forming and arranging a plurality of photosensitive elements in a two-dimensional array state in a light-receiving portion area of a semiconductor substrate;
forming signal reading circuits so as to correspond to the respective photosensitive elements, wherein each signal reading circuit is formed to detect a captured image signal corresponding to signal charges of the corresponding one of the photosensitive elements, the signal charges being accumulated in response to an amount of light which come from an object and is received by the corresponding one of the photosensitive elements; and
forming a first type wiring which is formed of a high-concentration impurity diffused layer, extend in one direction along a surface of the light-receiving portion area and is connected to plural ones of the signal reading circuits which are provided along the one direction.
